(19) United States
(12) Patent Application Publication
(10) Pub. No.: US 2024/0094246 A1
(43) Pub. Date: Mar. 21, 2024

(54) INSPECTION DEVICE FOR DISPLAY APPARATUS AND INSPECTION METHOD FOR DISPLAY APPARATUS

(71) Applicant: Samsung Display Co., Ltd., Yongin-si (KR)

(72) Inventor: Daewon Lee, Yongin-si (KR)

(73) Assignee: Samsung Display Co., Ltd., Yongin-si (KR)

(21) Appl. No.: 18/345,469

(22) Filed: Jun. 30, 2023

(30) Foreign Application Priority Data
Sep. 19, 2022 (KR) 10-2022-0118158

(51) Int. Cl. G01R 1/067; G01R 1/04; G01R 31/28

(52) U.S. Cl. CPC G01R 1/06705; G01R 1/04; G01R 31/2825

(57) ABSTRACT

An inspection device for a display apparatus includes a stage including a seating portion on which a target is seated and an opening portion located in the seating portion, an opening/closing module that opens or closes the opening portion, and an inspection module that inspects electrical characteristics of the target.

### CROSS-REFERENCE TO RELATED APPLICATION

This application claims priority to and benefits of Korean Patent Application No. 10-2022-0118158 under 35 U.S.C. § 119, filed in the Korean Intellectual Property Office on Sep. 19, 2022, the entire contents of which are incorporated herein by reference.

### BACKGROUND

### 1. Technical Field

One or more embodiments relate to an inspection device for a display apparatus and an inspection method for a display apparatus, which is capable of decreasing burning the display apparatus and preventing damage to the display apparatus.

### 2. Description of the Related Art

Mobility-based electronic devices are widely used. Recently, tablet personal computers (PCs), in addition to small electronic devices such as mobile phones, have been widely used as mobile electronic devices.

In order to support various functions, a mobile electronic device includes a display apparatus for providing visual information such as an image to a user. Recently, as other components for driving a display apparatus have been miniaturized, the proportion of the display apparatus in an electronic device has been gradually increased, and a structure that is bendable from a flat state by a certain angle has been developed.

It is to be understood that this background of the technology section is, in part, intended to provide useful background for understanding the technology. However, this background of the technology section may also include ideas, concepts, or recognitions that were not part of what was appreciated by those skilled in the pertinent art prior to a corresponding effective filing date of the subject matter disclosed herein.

### SUMMARY

One or more embodiments include an inspection device for a display apparatus, in which an opening portion is located on a seating portion where the display apparatus is seated, and the opening portion is closed in case that a voltage is applied to the display apparatus and the opening portion is opened when the display apparatus is detached.

However, embodiments of the disclosure are not limited to those set forth herein. The above and other embodiments will become more apparent to one of ordinary skill in the art to which the disclosure pertains by referencing the detailed description of the disclosure given below.

Additional aspects will be set forth in part in the description which follows and, in part, will be apparent from the description, or may be learned by practice of the embodiments.

According to one or more embodiments, an inspection device for a display apparatus includes a stage including a seating portion on which a target is seated and an opening portion located in the seating portion, an opening/closing module that opens or closes the opening portion, and an inspection module that inspects electrical characteristics of the target.

The opening/closing module may include a switch contacting the target on which the opening portion is closed, and a switch moving part that moves the switch.

The switch moving part may include a first moving part that moves the switch in a first direction so that the switch overlaps the opening portion in a plan view.

The switch moving part may further include a second moving part that moves the switch in a second direction intersecting the first direction so that at least part of the switch is located in the opening portion.

The switch moving part may include a hinge that rotates the switch about a rotational axis so that a surface of the switch is coplanar with the seating portion of the stage.

Each of the seating portion of the stage and the switch may include a metal material.

The opening portion may include a first opening portion including a first portion extending in a direction parallel to a seating direction in which the target is seated.

The first opening portion may further include a second portion extending from an end of the first portion in a direction intersecting the seating direction.

The opening portion may further include a second opening portion extending in a direction parallel to the seating direction. The second opening portion includes a 2-1^{th} opening portion, and a 2-2^{th} opening portion substantially symmetric to the 2-1^{th} opening portion with the first portion disposed between the 2-2^{th} opening portion and the 2-1^{th} opening portion.

The inspection module may further include an inspector including a probe that applies a voltage to a target and detects an electrical signal generated by the target, and an inspector moving part that moves the inspector so that the probe contacts the target.

According to one or more embodiments, an inspection method for a display apparatus includes seating a target on a seating portion of a stage, closing an opening portion located in the seating portion of the stage, inspecting electrical characteristics of the target, and opening the closed opening portion.

The closing of the opening portion may include moving a switch so that the switch contacts the target.

The moving of the switch may include moving the switch in a first direction so that the switch overlaps the opening portion in a plan view.

The moving of the switch may include moving the switch in a second direction intersecting the first direction so that at least part of the switch is located in the opening portion.

The closing of the opening portion may include rotating the switch about a rotational axis so that a surface of the switch is coplanar with the seating portion of the stage.

The inspecting of the electrical characteristics of the target may include moving a probe to contact the target, and applying a voltage to the target by the probe to detect an electrical signal generated by the target.

Each of the seating portion of the stage and the switch may include a metal material.

The opening portion may include a first opening portion including a first portion extending in a direction parallel to a seating direction in which the target is seated.

The first opening portion may further include a second portion extending from an end of the first portion in a direction intersecting the seating direction.

The opening portion may further include a second opening portion extending in a direction parallel to the seating direction. The second opening portion may include a 2-1^{th} opening portion, and a 2-2^{th} opening portion substantially symmetric to the 2-1^{th} opening portion with the first portion disposed between the 2-2^{th} opening portion and the 2-1^{th} opening portion.

Other aspects, features, and advantages of the disclosure will become more apparent from the drawings, the claims, and the detailed description.

### BRIEF DESCRIPTION OF THE DRAWINGS

An additional appreciation according to the embodiments of the disclosure will become more apparent by describing in detail the embodiments thereof with reference to the accompanying drawings, wherein:

FIG. 1 is a schematic perspective view illustrating an inspection device for a display apparatus, according to an embodiment;

FIG. 2 is a schematic side view illustrating an inspection device for a display apparatus, according to an embodiment;

FIG. 3 is a schematic side view illustrating an inspection device for a display apparatus, according to an embodiment;

FIG. 4 is a schematic plan view illustrating a part of an inspection device for a display apparatus, according to an embodiment;

FIG. 5 is a schematic cross-sectional view illustrating a part of an inspection device for a display apparatus, according to an embodiment;

FIG. 6 is a schematic plan view illustrating a part of an inspection device for a display apparatus, according to an embodiment;

FIG. 7 is a schematic cross-sectional view illustrating a part of an inspection device for a display apparatus, according to an embodiment;

FIG. 8 is a plan view schematically illustrating a display apparatus, according to an embodiment;

FIG. 9 is a cross-sectional view schematically illustrating a display apparatus manufactured by using a method of manufacturing a display apparatus, according to an embodiment;

FIG. 10 is a schematic diagram of an equivalent circuit illustrating a pixel included in a display panel, according to an embodiment;

FIG. 11 is a schematic plan view illustrating a part of an inspection device for a display apparatus, according to another embodiment;

FIG. 12 is a schematic cross-sectional view illustrating a part of an inspection device for a display apparatus, according to another embodiment;

FIG. 13 is a schematic plan view illustrating a part of an inspection device for a display apparatus, according to another embodiment;

FIG. 14 is a schematic cross-sectional view illustrating a part of an inspection device for a display apparatus, according to another embodiment;

FIG. 15 is a schematic plan view illustrating a part of an inspection device for a display apparatus, according to another embodiment;

FIG. 16 is a schematic cross-sectional view illustrating a part of an inspection device for a display apparatus, according to another embodiment;

FIG. 17 is a schematic plan view illustrating a part of an inspection device for a display apparatus, according to another embodiment; and

FIG. 18 is a schematic cross-sectional view illustrating a part of an inspection device for a display apparatus, according to another embodiment.

### DETAILED DESCRIPTION OF THE EMBODIMENTS

In the following description, for the purposes of explanation, numerous specific details are set forth in order to provide a thorough understanding of various embodiments or implementations of the disclosure. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the disclosure. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the disclosure.

For the purposes of this disclosure, the phrase “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

Hereinafter, like reference numerals and/or reference characters denote like elements.

Although the terms “first,” “second,” etc. may be used to describe various elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein should be interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise.

Moreover, the terms “comprises,” “comprising,” “includes,” and/or “including,” when used in this specification, specify the presence of the stated features, integers, steps, operations, elements, components, and/or groups thereof, but do not preclude the presence or addition of one or more other features, integers, steps, operations, elements, components, and/or groups thereof.

When an element, such as a layer, is referred to as being “on,” “connected to,” or “coupled to” another element or layer or intervening elements or layers maybe present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes.

In the following embodiments, the X-axis, the Y-axis and the Z-axis are not limited to three axes of a rectangular coordinate system, such as the x, y, and z axes, and may be interpreted in a broader sense. For example, the X-axis, the Y-axis, and the Z-axis may be perpendicular to one another, or may represent different directions that are not perpendicular to one another.

When an embodiment may be implemented differently, a specific process order may be performed differently from the described order. For example, two consecutively described processes may be performed substantially at the same time or performed in an order opposite to the described order.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the disclosure. Further, the blocks, units, and/or modules of some embodiments may be physically combined into more complex blocks, units, and/or modules without departing from the scope of the disclosure.

The terms “about” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein.

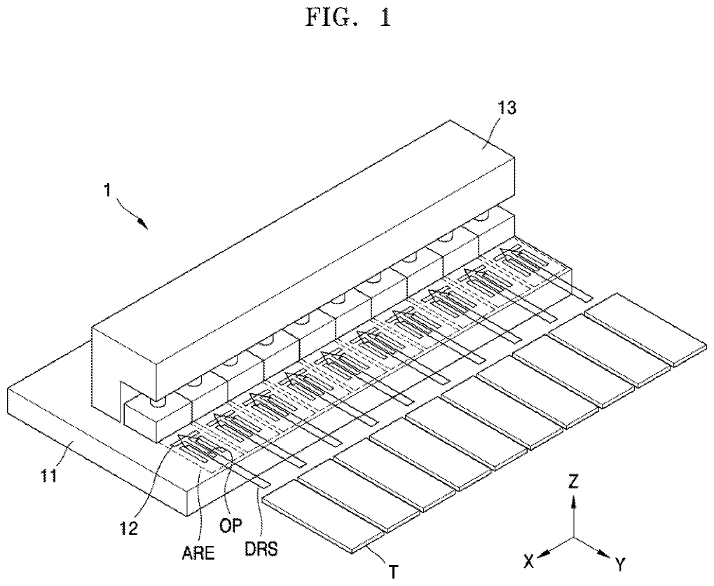

FIG. 1 is a schematic perspective view illustrating an inspection device for a display apparatus, according to an embodiment.

Referring to FIG. 1, an inspection device 1 for a display apparatus may inspect a target T. The inspection device 1 may age the target T. Aging (e.g., the aging of the target T) may be a process of testing reliability to determine whether the target T properly operates. The inspection device 1 may include a stage 11, an opening/closing module (or a switching module) 12, and an inspection module 13.

The target T may be a target to be inspected by the inspection device 1. The target T may include a flat surface. For example, as shown in FIG. 1, the target T may have a plate shape. Although the target T has a quadrangular planar shape in FIG. 1, the disclosure is not limited thereto, and the target T may have various shapes.

The stage 11 may provide a space where the target T is located in an inspection process of the inspection device 1. The stage 11 may include a seating portion ARE and an opening portion OP.

The target T may be seated on the seating portion ARE of the stage 11. The target T may be introduced in a seating direction DRS and seated on the seating portion ARE of the stage 11. For example, the seating direction DRS may be a Y-axis direction. The seating portion ARE of the stage 11 may be a flat surface, and the stage 11 may support a surface (e.g., a surface facing a Z-axis) of the target T on the seating portion ARE. For example, multiple seating portions ARE may be provided on the stage 11. Accordingly, multiple targets T may be seated on the seating portions ARE at a same time.

The opening portion OP may be located in the seating portion ARE of the stage 11. In case that the target T is seated on the seating portion ARE, and a gap may occur (or may be formed) between the stage 11 and the target T due to the opening portion OP. Although a planar shape of the opening portion OP is a shape obtained by combining a ‘T’ shape with a ‘l’ shape in FIG. 1, the disclosure is not limited thereto, and the opening portion OP may have various shapes.

The opening/closing module 12 may open or close the opening portion OP. The opening/closing module 12 may switch between a first state in which the opening/closing module 12 opens the opening portion OP and a second state in which the opening/closing module 12 closes the opening portion OP.

The inspection module 13 may inspect electrical characteristics of the target T. The inspection module 13 may be located on the stage 11. The inspection module 13 may be connected to the stage 11. Although the inspection module 13 and the stage 11 are directly connected to each other in FIG. 1, a separate member may be located between the inspection module 13 and the stage 11.

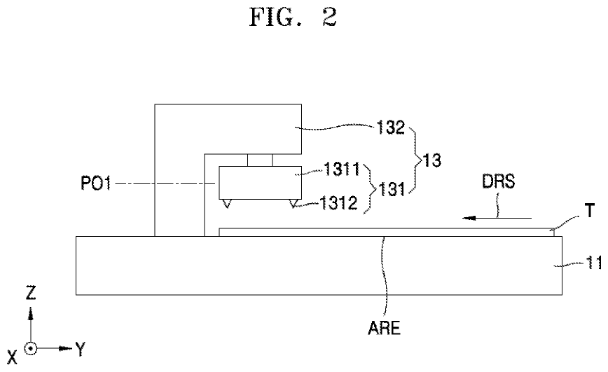

FIG. 2 is a schematic side view illustrating an inspection device for a display apparatus, according to an embodiment.

Referring to FIG. 2, the inspection module 13 may include an inspector 131 and an inspector moving part 132.

The inspector 131 may be located on the target T, and the target T may be seated on the seating portion ARE of the stage 11 in the seating direction DRS. For example, multiple inspectors 131 may be provided as shown in FIG. 1. The inspectors 131 may be aligned in parallel in a direction (e.g., an X-axis direction) intersecting the seating direction DRS. The inspector 131 may inspect multiple targets T at a same time. The inspector 131 may include an inspection frame 1311 and a probe 1312.

The inspection frame 1311 may form an outer appearance of the inspector 131. Although not shown in FIG. 2, electronic components may be located in an inner space of the inspector 131.

The probe 1312 may protrude from the inspection frame 1311. For example, the probe 1312 may protrude from a lower surface of the inspection frame 1311. The probe 1312 may include a sharp tip facing the target T. For example, multiple probes 1312 may be provided. Although two probes 1312 are provided in FIG. 2, the disclosure is not limited thereto, and the number of probes 1312 may be changed.

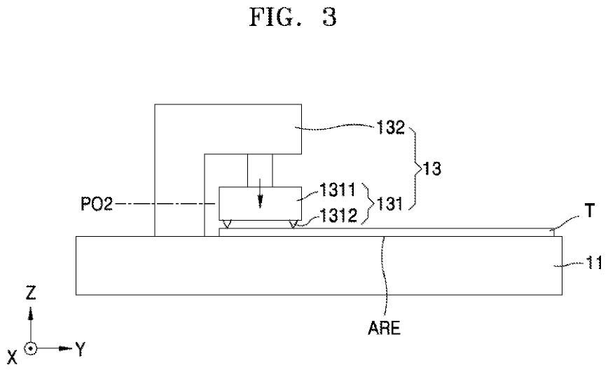

The inspector moving part 132 may move (e.g., reciprocate) the inspector 131 between a first position P01 and a second position P02 (e.g., refer to FIG. 3). The first position P01 may be a position at which the inspector 131 is spaced apart from the target T as shown in FIG. 2, and the second position P02 may be a position at which the inspector 131 contacts the target T as shown in FIG. 3 described below. The inspector moving part 132 may linearly move the inspector 131 in an inspection direction. For example, the inspection direction may be a Z-axis direction. The inspector moving part 132 may be connected to the inspection frame 1311. Since the inspector moving part 132 moves the inspection frame 1311, the probe 1312 connected to the inspection frame 1311 may also be moved.

FIG. 3 is a schematic side view illustrating an inspection device for a display apparatus, according to an embodiment.

In case that the target T is seated on the seating portion ARE of the stage 11, the inspector moving part 132 may move (e.g., move downwardly) the inspector 131, and the inspector 131 contacts the target T. For example, the inspector moving part 132 may move (e.g., move downwardly) the inspector 131 to the second position P02. Since the inspector moving part 132 moves the inspection frame 1311, the probe 1312 may contact the target T. The probe 1312 may apply a voltage to the target T and detect an electrical signal.

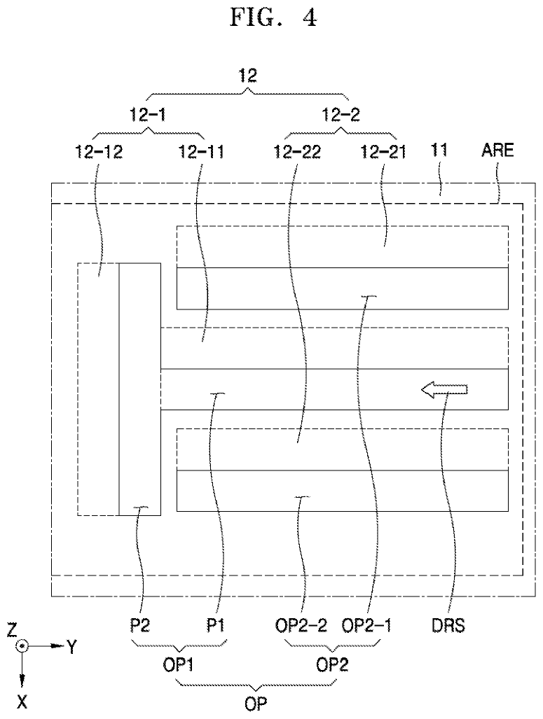

FIG. 4 is a schematic plan view illustrating a part of an inspection device for a display apparatus, according to an embodiment. FIG. 4 is a schematic view illustrating the first state in which the opening/closing module 12 opens the opening portion OP.

Referring to FIG. 4, the opening portion OP in a seating portion ARE may include a first opening portion OP1 and a second opening portion OP2.

The first opening portion OP1 may include a first portion P1 and a second portion P2. The first portion P1 may extend in a direction (e.g., a Y-axis direction) parallel to the seating direction DRS. The second portion P2 may extend from an end of the first portion P1 in a direction (e.g., the Z-axis direction) intersecting the seating direction DRS. For example, the second portion P2 may extend from an end of the first portion P1 facing the seating direction DRS. A planar shape of the first opening portion OP1 may include a ‘T’ shape.

The second opening portion OP2 may extend in the direction (e.g., the Y-axis direction) parallel to the seating direction DRS. The second opening portion OP2 may be spaced apart from the first opening portion OP1. The second portion P2 of the first opening portion OP1 may be spaced apart from the second opening portion OP2 in the seating direction DRS. The second opening portion OP2 may include a 2-1^{th} opening portion OP2-1 and a 2-2^{th} opening portion OP2-2. The 2-2^{th} opening portion OP2-2 may be substantially symmetric to the 2-1^{th} opening portion OP2-1 with the first portion P1 of the first opening portion OP1 therebetween. A planar shape of the 2-1^{th} opening portion OP2-1 and the 2-2^{th} opening portion OP2-2 may include a ‘l l’ shape. A sum of a distance between the first portion P1 and the 2-1^{th} opening portion OP2-1 and a distance between the first portion P1 and the 2-2^{th} opening portion OP2-2 may be equal to or less than a length of the second portion P2 in a longitudinal direction (e.g., the X-axis direction) of the second portion P2.

In the first state as shown in FIG. 4, the opening/closing module 12 may open the opening portion OP. The opening/closing module 12 may include a first opening/closing module 12-1 and a second opening/closing module 12-2.

The first opening/closing module 12-1 may open or close the first opening portion OP1. The first opening/closing module 12-1 may include a 1-1^{th} opening/closing module 12-11 and a 1-2^{th} opening/closing module 12-12. The 1-1^{th} opening/closing module 12-11 may open or close the first portion P1 of the first opening portion OP1. The 1-2^{th} opening/closing module 12-12 may open or close the second portion P2 of the first opening portion OP1. For example, as shown in FIG. 4, the 1-1^{th} opening/closing module 12-11 may open the first portion P1, and the 1-2^{th} opening/closing module 12-12 may open the second portion P2.

The second opening/closing module 12-2 may open or close the second opening portion OP2. The second opening/closing module 12-2 may include a 2-1^{th} opening/closing module 12-21 and a 2-2^{th} opening/closing module 12-22. The 2-1^{th} opening/closing module 12-21 may open or close the 2-1^{th} opening portion OP2-1. The 2-2^{th} opening/closing module 12-22 may open or close the 2-2^{th} opening portion OP2-2. For example, as shown in FIG. 4, the 2-1^{th} opening/closing module 12-21 may open the 2-1^{th} opening portion OP2-1, and the 2-2^{th} opening/closing module 12-22 may open the 2-2^{th} opening portion OP2-2.

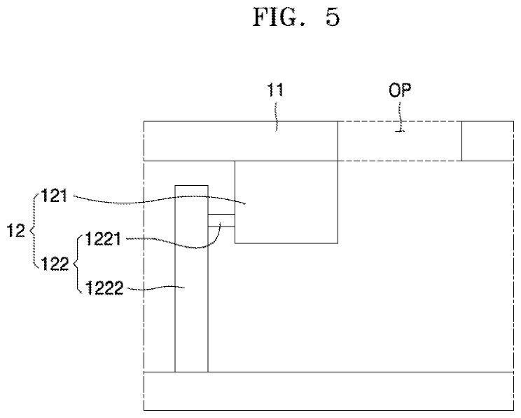

FIG. 5 is a schematic cross-sectional view illustrating a part of an inspection device for a display apparatus, according to an embodiment. FIG. 5 is a schematic view illustrating the first state in which the opening/closing module 12 opens the opening portion OP.

Referring to FIG. 5, the opening/closing module 12 may include a switch (or an opening/closing part) 121 and a switch moving part 122.

In the first state as shown in FIG. 5, the switch 121 may not overlap the opening portion OP in a plan view. A surface (e.g., a surface facing the +Z-axis of FIG. 4) of the switch 121 may contact the stage 11. The switch 121 may contact the opening portion OP. The switch moving part 122 may move the switch 121. The switch moving part 122 may include a first moving part 1221 and a second moving part 1222. The first moving part 1221 may move the switch 121 in a first direction. For example, the first direction of the first moving part 1221 of the 1-1^{th} opening/closing module 12-11 (e.g., refer to FIG. 4), the 2-1^{th} opening/closing module 12-21 (e.g., refer to FIG. 4), and the 2-2^{th} opening/closing module 12-22 (e.g., refer to FIG. 4) may be the X-axis direction (e.g., refer to FIG. 4), and the first direction of the 1-2^{th} opening/closing module 12-12 (e.g., refer to FIG. 4) may be the Y-axis direction (e.g., refer to FIG. 4). The second moving part 1222 may move the switch 121 in a second direction intersecting the first direction. For example, the second direction may be the Z-axis direction (e.g., refer to FIG. 4).

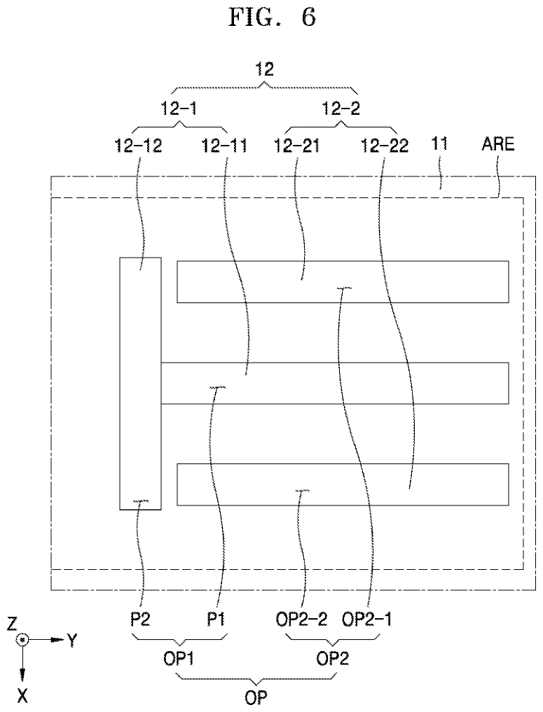

FIG. 6 is a schematic plan view illustrating a part of an inspection device for a display apparatus, according to an embodiment. FIG. 6 is a schematic view illustrating the second state in which the opening/closing module 12 closes the opening portion OP.

In FIG. 6, the same members as those in FIG. 4 are denoted by the same reference numerals, and thus, a repeated description thereof will be omitted.

In the second state as shown in FIG. 6, the opening/closing module 12 may close the opening portion OP. For example, the 1-1^{th} opening/closing module 12-11 may close the first portion P1, and the 1-2^{th} opening/closing module 12-12 may close the second portion P2. In the second state, the 1-1^{th} opening/closing module 12-11 and the 1-2^{th} opening/closing module 12-12 may contact each other. Also, the 2-1^{th} opening/closing module 12-21 may close the 2-1^{th} opening portion OP2-1, and the 2-2^{th} opening/closing module 12-22 may close the 2-2^{th} opening portion OP2-2. In the second state, the 2-1^{th} opening/closing module 12-21 and the 2-2^{th} opening/closing module 12-22 may be substantially symmetric to each other with the 1-1^{th} opening/closing module 12-11 therebetween.

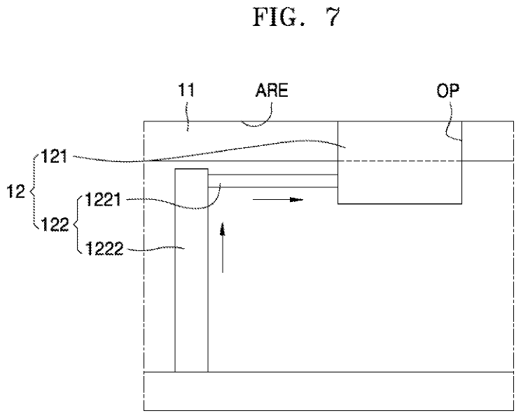

FIG. 7 is a schematic cross-sectional view illustrating a part of an inspection device for a display apparatus, according to an embodiment. FIG. 7 is a schematic view illustrating the second state in which the opening/closing module 12 closes the opening portion OP.

In FIG. 7, the same members as those in FIG. 5 are denoted by the same reference numerals, and thus, a repeated description thereof will be omitted.

In the second state as shown in FIG. 7, the switch 121 may be located to close the opening portion OP. A shape of the switch 121 may correspond to a shape of the opening portion OP. For example, when a planar shape of the opening portion OP includes a quadrangular shape, a planar shape of the switch 121 may include a quadrangular shape.

Accordingly, the switch 121 may close (e.g., completely close) the opening portion OP. In the second state, a surface (e.g., a surface facing the +Z-axis of FIG. 6) of the switch 121 may be coplanar with the seating portion ARE of the stage 11. Accordingly, in case that the opening portion OP is closed, the switch 121 may contact the target T (e.g., refer to FIG. 1).

The switch moving part 122 may move the switch 121, and the switch 121 may close the opening portion OP. After an operation of the first moving part 1221 is completed, an operation of the second moving part 1222 may start. The first moving part 1221 may move the switch 121 in the first direction, and the switch 121 may overlap the opening portion OP in a plan view. The first direction may be a direction toward the opening portion OP in a plan view. For example, the first direction of the first moving part 1221 of the 1-1^{th} opening/closing module 12-11 (e.g., refer to FIG. 6), the 2-1^{th} opening/closing module 12-21 (e.g., refer to FIG. 6), and the 2-2^{th} opening/closing module 12-22 (e.g., refer to FIG. 6) may be the +X-axis direction (e.g., refer to FIG. 6), and the first direction of the 1-2^{th} opening/closing module 12-12 may be the +Y-axis direction (e.g., refer to FIG. 6). The second moving part 1222 may move the switch 121 in the second direction, and at least part of the switch 121 may be located in the opening portion OP. The second direction may be a direction toward the opening portion OP in a cross-sectional view. For example, the second direction may be the +Z-axis direction (e.g., refer to FIG. 6).

Accordingly, a surface (e.g., a surface facing the +Z-axis of FIG. 6) of the switch 121 may be coplanar with the seating portion ARE of the stage 11.

Detailed description of an inspection method for a display apparatus is provided with reference to FIGS. 2 to 7.

As shown in FIG. 2, in case that the inspector 131 is located at the first position P01, the target T may be seated on the seating portion ARE of the stage 11.

As shown in FIG. 3, the inspector moving part 132 may move the inspector 131 to the second position P02, and the inspector 131 may inspect electrical characteristics of the target T. The seating portion ARE of the stage 11 may include a metal material. Accordingly, the probe 1312 may apply a voltage to the target T, heat may be generated in the target T, and the seating portion ARE of the stage 11 formed of a metal material may cool the target T.

However, in case that the opening portion OP is opened, the target T overlapping the opening portion OP in a plan view may not be cooled by the seating portion ARE of the stage 11. Thus, burning may partially occur in the target T. Accordingly, the switch 121 may include a metal material. Also, as shown in FIGS. 6 and 7, the inspector 131 may inspect electrical characteristics of the target T, and the opening/closing module 12 may close the opening portion OP. In case that the switch moving part 122 moves the switch 121 from the first position P01 to the second position P02, the opening/closing module 2 may switch from the first state to the second state. Accordingly, the switch 121 including a metal material may contact the target T, and the target T may be cooled. Accordingly, burning partially occurring at a portion of the target T overlapping the opening portion OP in a plan view may be reduced (or prevented).

In case that the process of inspecting the electrical characteristics of the target T ends, as shown in FIG. 2, the inspector moving part 132 may move the inspector 131 back to the first position PO1. The target T may be taken out from the seating portion ARE of the stage 11. In case that the target T is taken out, the target T may be damaged due to adsorption occurring between the target T and the seating portion ARE of the stage 11. Accordingly, in case that the process of inspecting the electrical characteristics of the target T ends, the opening/closing module 12 may open the opening portion OP. In case that the switch moving part 122 moves the switch 121 from the second position P02 to the first position P01, the opening/closing module 12 may switch from the second state to the first state. Accordingly, a gap may occur between the stage 11 and the target T in the opening portion OP. The target T may be taken out from the seating portion ARE of the stage 11, and air may flow through the opening portion OP. For example, the opening portion OP may function as an air path. The target T may be readily separated from the seating portion ARE of the stage 11. Accordingly, damage to the target T occurred during withdrawal of the target T may be reduced.

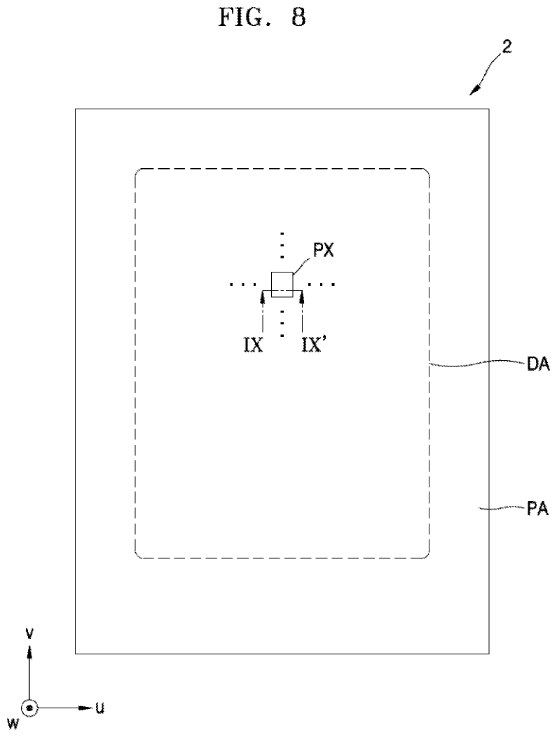

FIG. 8 is a plan view schematically illustrating a display apparatus, according to an embodiment.

Referring to FIG. 8, a display apparatus 2 manufactured according to an embodiment may include a display area DA and a peripheral area PA located outside the display area DA. The display apparatus 2 may provide an image in a front direction (e.g., w-axis direction) through an array of pixels PX that are two-dimensionally arranged (e.g., arranged in a plane of u-axis direction and v-axis direction) in the display area DA.

The peripheral area PA where an image is not provided may entirely or partially surround the display area DA. A driver or the like for providing an electrical signal or power to a pixel circuit corresponding to each of the pixels PX may be located in the peripheral area PA. A pad to which an electronic device, a printed circuit board, or the like are electrically connected may be located in the peripheral area PA.

Although the display apparatus 2 includes an organic light-emitting diode (OLED) as a light-emitting element, the display apparatus 2 of the disclosure is not limited thereto. In another embodiment, the display apparatus 2 may be a light-emitting display apparatus (e.g., an inorganic light-emitting display apparatus) including an inorganic light-emitting diode. The inorganic light-emitting diode may include a PN diode including inorganic semiconductor-based materials. in case that a voltage is applied to a PN junction diode in a forward direction, holes and electrons may be injected, and energy generated by recombination of the holes and electrons may be converted into light energy to emit light of a color (e.g., a certain or selectable color). The inorganic light-emitting diode may have a width of several to hundreds of micrometers, and in some embodiments, the inorganic light-emitting diode may be referred to as a micro-LED. In another embodiment, the display apparatus 2 may be a quantum dot light-emitting display apparatus.

The display apparatus 2 may be used as a display screen of a portable electronic device such as a mobile phone, a smartphone, a tablet personal computer (PC), a mobile communication terminal, an electronic organizer, an electronic book, a portable multimedia player (PMP), a navigation device, or an ultra-mobile PC (UMPC). For example, the display apparatus 2 may be used as any of various products such as a television, a laptop computer, a monitor, an advertisement board, or an Internet of things (IoT) device. Also, the display apparatus 2 according to an embodiment may be used in a wearable device such as a smart watch, a watch phone, a glasses-type display, or a head-mounted display (HMD). Also, the display apparatus 2 according to an embodiment may be applied to a center information display (CID) located on an instrument panel, a center fascia, or a dashboard of a vehicle, a room mirror display replacing a side-view mirror of a vehicle, or a display screen located on the back of a front seat for entertainment for a back seat of a vehicle.

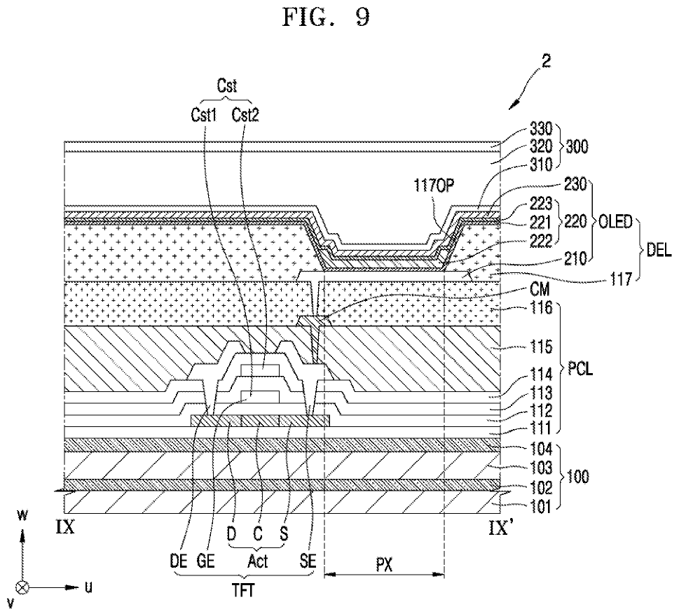

FIG. 9 is a cross-sectional view schematically illustrating a display apparatus manufactured by using a method of manufacturing a display apparatus, taken along line IX-IX′ of FIG. 8, according to an embodiment.

Referring to FIG. 9, the display apparatus 2 may have a substrate 100, a pixel circuit layer PCL, a display element layer DEL, and an encapsulation layer 300 which are stacked one another.

The substrate 100 may have a multi-layer structure including a base layer including a polymer resin and an inorganic layer. For example, the substrate 100 may include abase layer including a polymer resin and a barrier layer of an inorganic insulating layer. For example, the substrate 100 may include a first base layer 101, a first barrier layer 102, a second base layer 103, and a second barrier layer 104 which are sequentially stacked. Each of the first base layer 101 and the second base layer 103 may include at least one of polyimide (PI), polyethersulfone (PES), polyarylate, polyetherimide (PEI), polyethylene napthalate (PEN), polyethylene terephthalate (PET), polyphenylene sulfide (PPS), polycarbonate, cellulose triacetate (TAC), and cellulose acetate propionate (CAP). Each of the first barrier layer 102 and the second barrier layer 104 may include an inorganic insulating material such as silicon oxide, silicon oxynitride, and/or silicon nitride. The substrate 100 may be flexible.

The pixel circuit layer PCL may be located on the substrate 100. In FIG. 9, the pixel circuit layer PCL may include a thin-film transistor TFT, a buffer layer 111, a first gate insulating layer 112, a second gate insulating layer 113, an interlayer insulating layer 114, a first planarization insulating layer 115, and a second planarization insulating layer 116. The buffer layer 111, the first gate insulating layer 112, the second gate insulating layer 113, the interlayer insulating layer 114, the first planarization insulating layer 115, and the second planarization insulating layer 116 may be located under and/or over elements of the thin-film transistor TFT.

The buffer layer 111 may reduce or block penetration of a foreign material, moisture, or external air from the bottom of the substrate 100, and may planarize the substrate 100. The buffer layer 111 may include an inorganic insulating material such as silicon oxide, silicon oxynitride, or silicon nitride, and may have a single or multi-layer structure including the above material.

The thin-film transistor TFT on the buffer layer 111 may include a semiconductor layer Act, and the semiconductor layer Act may include polysilicon. As another example, the semiconductor layer Act may include amorphous silicon, an oxide semiconductor, or an organic semiconductor. The semiconductor layer Act may include a channel region C, a drain region D, and a source region S. The drain region F and the source region S may be located on sides (e.g., both sides) of the channel region C. A gate electrode GE may overlap the channel region C in a plan view.

The gate electrode GE may include a low-resistance metal material. The gate electrode GE may include a conductive material including at least one of molybdenum (Mo), aluminum (Al), copper (Cu), and titanium (Ti), and may have a single or multi-layer structure including the above material.

The first gate insulating layer 112 may be disposed between the semiconductor layer Act and the gate electrode GE. The first gate insulating layer 112 may include an inorganic insulating material such as silicon oxide (SiO₂), silicon nitride (SiN_{X}), silicon oxynitride (SiON), aluminum oxide (Al₂O₃), titanium oxide (TiO₂), tantalum oxide (Ta₂O₅), hafnium oxide (HfO₂), or zinc oxide (ZnOₓ). Zinc oxide (ZnOₓ) may be zinc oxide (ZnO) and/or zinc peroxide (ZnO₂).

The second gate insulating layer 113 may cover the gate electrode GE. The second gate insulating layer 113 may include an inorganic insulating material such as silicon oxide (SiO₂), silicon nitride (SiN_{X}), silicon oxynitride (SiON), aluminum oxide (Al₂O₃), titanium oxide (TiO₂), tantalum oxide (Ta₂O₅), hafnium oxide (HfO₂), or zinc oxide (ZnOₓ). For example, the second gate insulating layer 113 and the first gate insulating layer 112 may include a same or similar material. Zinc oxide (ZnOₓ) may be zinc oxide (ZnO) and/or zinc peroxide (ZnO₂).

An upper electrode Cst2 of a storage capacitor Cst may be located on the second gate insulating layer 113. The upper electrode Cst2 may overlap the gate electrode GE in a plan view, which is located below the upper electrode Cst2. The gate electrode GE and the upper electrode Cst2 overlapping each other in a plan view with the second gate insulating layer 113 therebetween may constitute the storage capacitor Cst. For example, the gate electrode GE may function as a lower electrode Cst1 of the storage capacitor Cst.

Thus, the storage capacitor Cst and the thin-film transistor TFT may overlap each other in a plan view. In some embodiments, the storage capacitor Cst may not overlap the thin-film transistor TFT in a plan view.

The upper electrode Cst2 may include at least one of aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), and copper (Cu), and may have a single or multi-layer structure including the above material.

The interlayer insulating layer 114 may cover the upper electrode Cst2. The interlayer insulating layer 114 may include at least one of silicon oxide (SiO₂), silicon nitride (SiN_{X}), silicon oxynitride (SiON), aluminum oxide (Al₂O₃), titanium oxide (TiO₂), tantalum oxide (Ta₂O₅), hafnium oxide (HfO₂), and zinc oxide (ZnOₓ). Zinc oxide (ZnOₓ) may be zinc oxide (ZnO) and/or zinc peroxide (ZnO₂). The interlayer insulating layer 114 may have a single or multi-layer structure including the above inorganic insulating material.

Each of a drain electrode DE and a source electrode SE may be located on the interlayer insulating layer 114. The drain electrode DE and the source electrode SE may be respectively connected (e.g., electrically connected) to the drain region D and the source region S through contact holes formed in insulating layers (e.g., the first gate insulating layer 112, the second gate insulating layer 113, and the interlayer insulating layer 114) under the drain electrode DE and the source electrode SE. Each of the drain electrode DE and the source electrode SE may include a material having excellent conductivity. Each of the drain electrode DE and the source electrode SE may include a conductive material such as molybdenum (Mo), aluminum (Al), copper (Cu), and titanium (Ti), and may have a single or multi-layer structure including the above material. In an embodiment, each of the drain electrode DE and the source electrode SE may have a multi-layer structure including Ti/Al/Ti.

The first planarization layer 115 may cover the drain electrode DE and the source electrode SE. The first planarization insulating layer 115 may include an organic insulating material such as a general-purpose polymer (e.g., polymethyl methacrylate (PMMA) or polystyrene (PS)), a polymer derivative having a phenol-based group, an acrylic polymer, an imide-based polymer, an aryl ether-based polymer, an amide-based polymer, a fluorinated polymer, a p-xylene-based polymer, a vinyl alcohol-based polymer, and a blend thereof.

The second planarization insulating layer 116 may be located on the first planarization insulating layer 115. The second planarization insulating layer 116 and the first planarization insulating layer 115 may include a same material, and the second planarization insulating layer 116 may include an organic insulating material such as a general-purpose polymer (e.g., PMMA or PS), a polymer derivative having a phenol-based group, an acrylic polymer, an imide-based polymer, an aryl ether-based polymer, an amide-based polymer, a fluorinated polymer, a p-xylene-based polymer, a vinyl alcohol-based polymer, or a blend thereof.

The display element layer DEL may be located on the pixel circuit layer PCL having the above structure. The display element layer DEL may include an organic light-emitting diode OLED as a display element (i.e., a light-emitting element), and the organic light-emitting diode OLED may have a structure in which a pixel electrode 210, an intermediate layer 220, and a common electrode 230 are stacked one another. The organic light-emitting diode OLED may emit, for example, red light, green light, or blue light, or may emit red light, green light, blue light, or white light. The organic light-emitting diode OLED may emit light through an emission area, and the emission area may be defined as the pixel PX.

The pixel electrode 210 of the organic light-emitting diode OLED may be electrically connected to the thin-film transistor TFT through a contact metal CM located on the first planarization insulating layer 115. The pixel electrode 210 may be electrically connected to the contact metal CM through a contact formed through the second planarization insulating layer 116. The contact metal CM may be electrically connected to the source electrode SE of the thin-film transistor TFT through a contact hole formed through the first planarization insulating layer 115.

The pixel electrode 210 may include a conductive oxide such as indium tin oxide (ITO), indium zinc oxide (IZO), zinc oxide (ZnO), indium oxide (In₂O₃), indium gallium oxide (IGO), or aluminum zinc oxide (AZO). In another embodiment, the pixel electrode 210 may include a reflective film including at least one of silver (Ag), magnesium (Mg), aluminum (Al), platinum (Pt), palladium (Pd), gold (Au), nickel (Ni), neodymium (Nd), iridium (Ir), and chromium (Cr). For example, the pixel electrode 210 may include a compound thereof. In another embodiment, the pixel electrode 210 may further include a film including at least one of ITO, IZO, ZnO, and In₂O₃ which is disposed over/under the reflective film.

A pixel-defining film 117 having an opening 1170P through which a central portion of the pixel electrode 210 is exposed may be located on the pixel electrode 210. The pixel-defining film 117 may include an organic insulating material and/or an inorganic insulating material. The opening 1170P may define the emission area of light emitted by the organic light-emitting diode OLED. For example, a size/width of the opening 1170P may correspond to a size/width of the emission area. Accordingly, a size and/or a width of the pixel PX may depend on a size and/or a width of the opening 1170P of the pixel-defining film 117.

The intermediate layer 220 may include an emission layer 222 formed to correspond to the pixel electrode 210. The emission layer 222 may include a high molecular weight organic material or a low molecular weight organic material that emits light of a color (e.g., a certain or selectable color). As another example, the emission layer 222 may include an inorganic light-emitting material or may include quantum dots.

In an embodiment, the intermediate layer 220 may include a first functional layer 221 located under the emission layer 222 and a second functional layer 223 located over the emission layer 222. The first functional layer 221 may include, for example, a hole transport layer (HTL). In some embodiments, the first functional layer 221 may include an HTL and a hole injection layer (HIL). The second functional layer 223 located on the emission layer 222 may include an electron transport layer (ETL) and/or an electron injection layer (EIL). The first functional layer 221 and/or the second functional layer 223 may be a common layer covering (e.g., entirely covering) the substrate 100, like the common electrode 230 described below.

The common electrode 230 may be located on the pixel electrode 210 and may overlap the pixel electrode 210 in a plan view. The common electrode 230 may be formed of a conductive material having a low work function. For example, the common electrode 230 may include a transparent layer (e.g., a semi-transparent layer) including at least one of silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), and an alloy thereof. As another example, the common electrode 230 may further include a layer including at least one of ITO, IZO, ZnO, and In₂O₃ on the transparent layer (e.g., a semi-transparent layer) including the above material. The common layer 230 may be integrally formed to cover (e.g., to entirely cover) the substrate 100.

The encapsulation layer 300 may be located on the display element layer DEL and may cover the display element layer DEL. The encapsulation layer 300 may include at least one inorganic encapsulation layer and at least one organic encapsulation layer. In an embodiment, in FIG. 9, the encapsulation layer 300 may include a first inorganic encapsulation layer 310, an organic encapsulation layer 320, and a second inorganic encapsulation layer 330 which are sequentially stacked.

Each of the first inorganic encapsulation layer 310 and the second inorganic encapsulation layer 330 may include at least one inorganic material of aluminum oxide, titanium oxide, tantalum oxide, hafnium oxide, zinc oxide, silicon oxide, silicon nitride, and silicon oxynitride. The organic encapsulation layer 320 may include a polymer-based material. Examples of the polymer-based material may include at least one of an acrylic resin, an epoxy resin, polyimide, and polyethylene. In an embodiment, the organic encapsulation layer 320 may include acrylate. The organic encapsulation layer 320 may be formed by curing a monomer or applying a polymer. The organic encapsulation layer 320 may be transparent.

Although not shown, a touch sensor (not illustrated) layer may be located on the encapsulation layer 300, and an optical functional layer (not illustrated) may be located on the touch sensor layer. The touch sensor layer may obtain coordinate information according to an external input, for example, a touch event. The optical functional layer may reduce a reflectance of light (external light) incident on a display apparatus, and/or improve color purity of light emitted from the display apparatus. In an embodiment, the optical functional layer may include a phase retarder (not illustrated) and/or a polarizer (not illustrated). The phase retarder may be a film-type phase retarder or a liquid crystal coating-type phase retarder, and may include a V/2 phase retarder and/or a V/4 phase retarder. The polarizer may also be a film-type polarizer or a liquid crystal coating-type polarizer. The film-type polarizer may include a stretchable synthetic resin film, and the liquid crystal coating-type polarizer may include liquid crystals arranged in an arrangement (e.g., a certain or selectable arrangement). The phase retarder and the polarizer may further include a protective film.

An adhesive member (not illustrated) may be located between the touch sensor layer and the optical functional layer. The adhesive member may include various suitable materials without limitation. The adhesive member may be a pressure sensitive adhesive (PSA).

The target T described with reference to FIGS. 1 to 7 may include the display apparatus 2 described with reference to FIG. 9. For example, the target T may include at least one of the substrate 100, the pixel circuit layer PCL, the display element layer DEL, and the encapsulation layer 300.

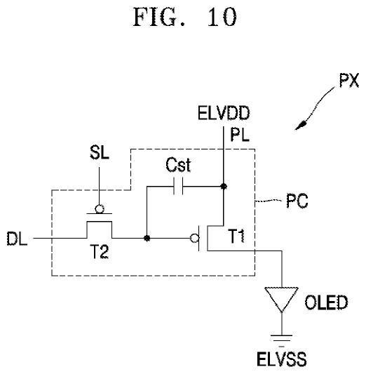

FIG. 10 is a schematic diagram of an equivalent circuit illustrating a pixel included in a display panel, according to an embodiment.

Each pixel PX may include a pixel circuit PC and a display element (e.g., an organic light-emitting diode OLED) electrically connected to the pixel circuit PC. The pixel circuit PC may include a first thin-film transistor T1, a second thin-film transistor T2, and a storage capacitor Cst. Each pixel PX may emit light (e.g., red light, green light, blue light, or white light) through the OLED.

The second thin-film transistor T2 that is a switching thin-film transistor may be electrically connected to a scan line SL and a data line DL, and may transmit a data voltage input from the data line DL to the first thin-film transistor T1 based on a switching voltage input from the scan line SL. The storage capacitor Cst may be electrically connected to the second thin-film transistor T2 and a driving voltage line PL, and may store a voltage corresponding to a difference between a voltage received from the second thin-film transistor T2 and a first power supply voltage ELVDD supplied to the driving voltage line PL.

The first thin-film transistor T1 that is a driving thin-film transistor may be electrically connected to the driving voltage line PL and the storage capacitor Cst, and may control driving current flowing from the driving voltage line PL to the organic light-emitting diode OLED according to a value of the voltage stored in the storage capacitor Cst. The organic light-emitting diode OLED may emit light having a luminance (e.g., a certain or selectable luminance) due to the driving current. A counter electrode (e.g., a cathode) of the organic light-emitting diode OLED may receive a second power supply voltage ELVSS.

Although the sub-pixel circuit PC includes two thin-film transistors (e.g., the first thin-film transistor T1 and the second thin-film transistor T2) and a storage capacitor (e.g., the storage capacitor Cst) in FIG. 10, the disclosure is not limited thereto. The number of thin-film transistors and the number of storage capacitors may be changed in various ways according to a design of the pixel circuit PC. For example, the pixel circuit PC may further include three or more thin-film transistors in addition to the above two thin-film transistors.

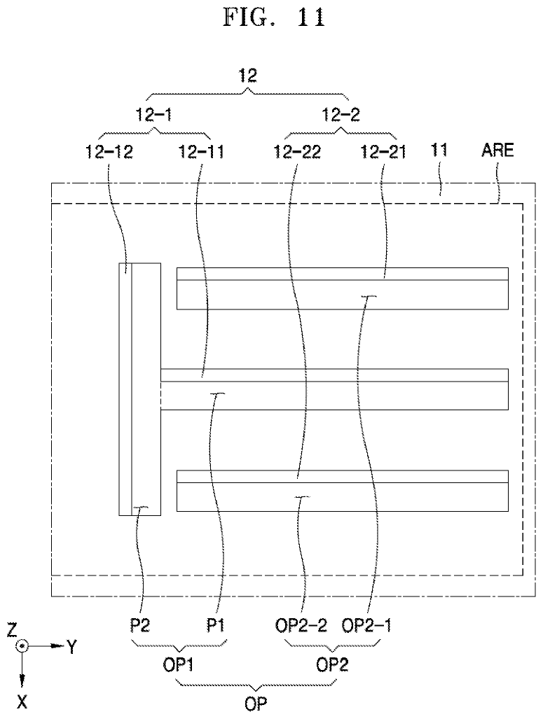

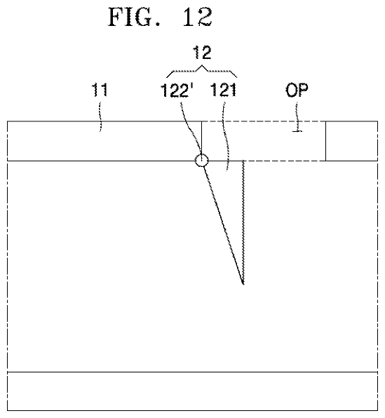

FIG. 11 is a schematic plan view illustrating a part of an inspection device for a display apparatus, according to another embodiment. FIG. 12 is a schematic cross-sectional view illustrating a part of an inspection device for a display apparatus, according to another embodiment. FIGS. 11 and 12 are schematic views illustrating the first state in which the opening/closing module 12 opens the opening portion OP.

In FIGS. 11 and 12, the same members as those in FIGS. 4 and 5 are denoted by the same reference numerals, and thus, a repeated description thereof will be omitted.

Referring to FIGS. 11 and 12, a switch moving part 122′ may include a hinge.

The switch moving part 122′ may connect the switch 121 to the stage 11, and may rotate the switch 121 about a rotational axis. For example, the rotational axis may be an axis perpendicular to the Z-axis. For example, a rotational axis of a switch moving part 122′ of the 1-1^{th} opening/closing module 12-11, a rotational axis of a switch moving part 122′ of the 2-1^{th} opening/closing module 12-21, and a rotational axis of a switch moving part 122′ of the 2-2^{th} opening/closing module 12-22 may be the Y-axis, and a rotational axis of a switch moving part 122′ of the 1-2^{th} opening/closing module 12-12 may be the X-axis.

A cross-sectional shape of the switch 121 may be a triangular shape. Accordingly, the switch moving part 122′ may rotate the switch 121, and the switch 121 may freely rotate without being caught by the stage 11. However, the disclosure is not limited thereto, and the switch 121 may have various shapes. In the first state as shown in FIGS. 11 and 12, the switch moving part 122′ may rotate the switch 121, and the switch 121 may open the opening portion OP.

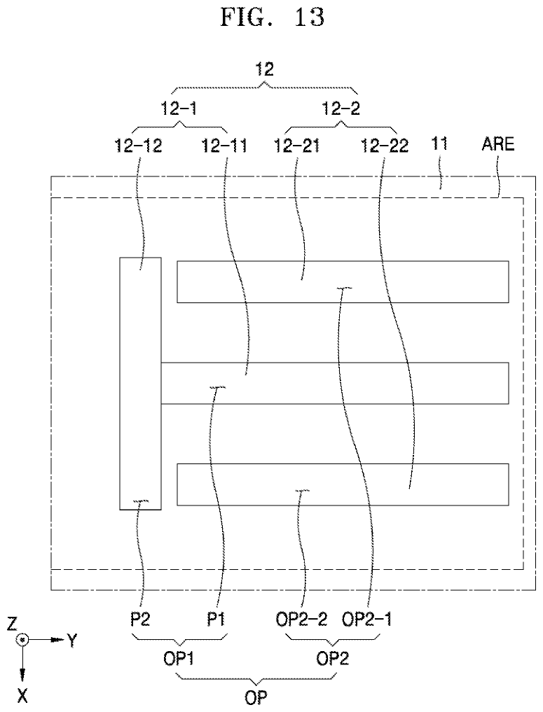

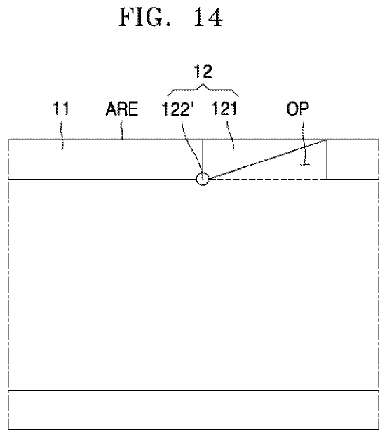

FIG. 13 is a schematic plan view illustrating a part of an inspection device for a display apparatus, according to another embodiment. FIG. 14 is a schematic cross-sectional view illustrating a part of an inspection device for a display apparatus, according to another embodiment. FIGS. 13 and 14 are schematic views illustrating the second state in which the opening/closing module 12 closes the opening portion OP.

In FIGS. 13 and 14, the same members as those in FIGS. 11 and 12 are denoted by the same reference numerals, and thus, a repeated description thereof will be omitted.

In the second state, the hinge of the switch moving part 122′ may rotate the switch 121, and the switch 121 closes the opening portion OP. A surface of the switch 121 and a corner of the switch 121 may contact the stage 11. Accordingly, the switch 121 may close (e.g., completely close) the opening portion OP. In the second state, a surface of the switch 121 and the seating portion ARE of the stage 11 may be coplanar with each other. Accordingly, in case that the target T (e.g., refer to FIG. 1) is seated on the seating portion ARE of the stage 11, the switch 121 may contact the target T.

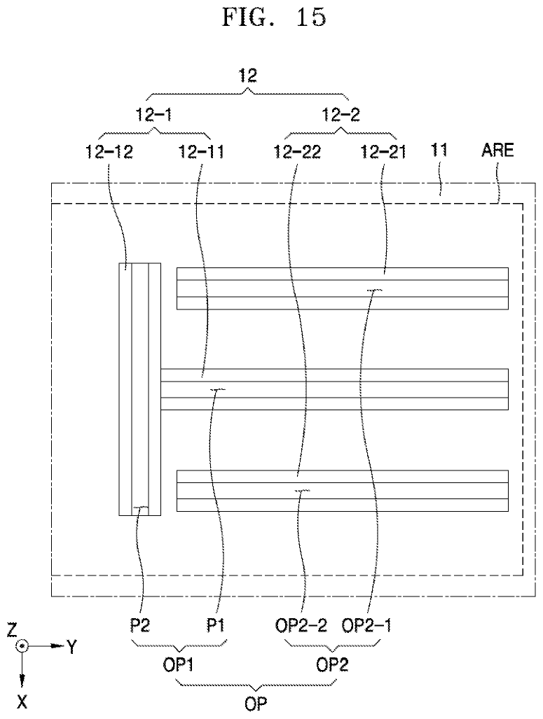

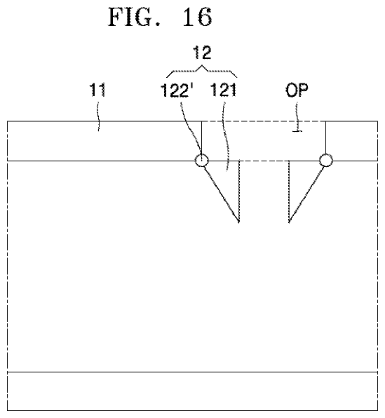

FIG. 15 is a schematic plan view illustrating a part of an inspection device for a display apparatus, according to another embodiment. FIG. 16 is a schematic cross-sectional view illustrating a part of an inspection device for a display apparatus, according to another embodiment. FIGS. 15 and 16 are schematic views illustrating the first state in which the opening/closing module 12 opens the opening portion OP.

In FIGS. 15 and 16, the same members as those in FIGS. 11 and 12 are denoted by the same reference numerals, and thus, a repeated description thereof will be omitted.

Referring to FIGS. 15 and 16, multiple opening/closing modules 12 may be provided for an opening portion OP. For example, two opening/closing modules 12 may be provided in each of the first portion P1 of the first opening portion OP1, the second portion P2 of the first opening portion OP1, the 2-1^{th} opening portion OP2-1, and the 2-2^{th} opening portion OP2-2.

The switch moving part 122′ may include a hinge. The switch moving part 122′ may connect the switch 121 to the stage 11, and may rotate the switch 121 about a rotational axis. For example, the rotational axis may be an axis perpendicular to the Z-axis.

A cross-sectional shape of the switch 121 may be a triangular shape. Accordingly, the switch moving part 122′ may rotate the switch 121, and two switches 121 may freely rotate without being caught by each other. However, the disclosure is not limited thereto, and the switch 121 may have various shapes. In the first state as shown in FIGS. 15 and 16, the switch moving part 122′ may rotate the switches 121, and the switches 121 may open the opening portion OP.

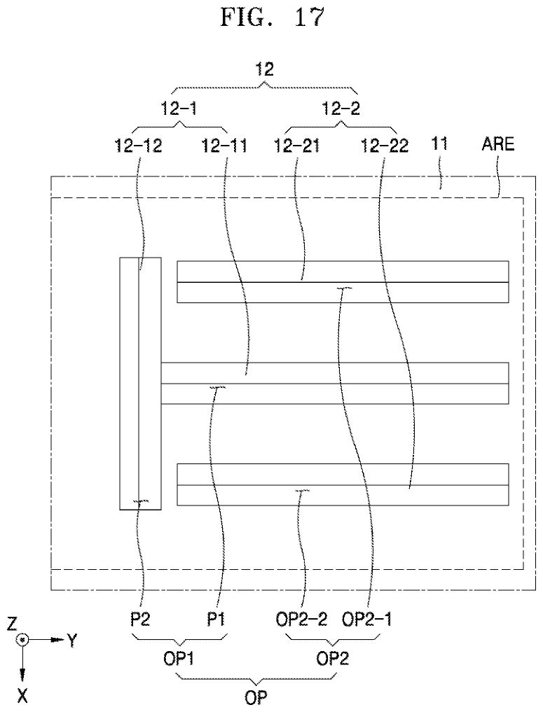

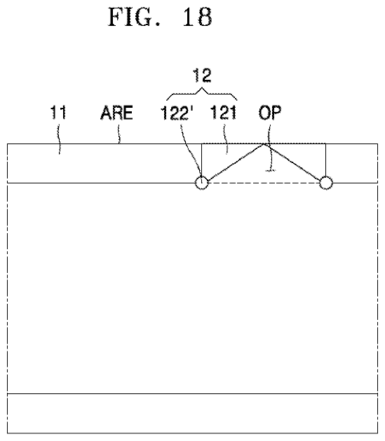

FIG. 17 is a schematic plan view illustrating a part of an inspection device for a display apparatus, according to another embodiment. FIG. 18 is a schematic cross-sectional view illustrating a part of an inspection device for a display apparatus, according to another embodiment. FIGS. 17 and 18 are schematic views illustrating the second state in which the opening/closing module 12 closes the opening portion OP.

In FIGS. 17 and 18, the same members as those in FIGS. 15 and 16 are denoted by the same reference numerals, and thus, a repeated description thereof will be omitted.

In the second state, the hinge of the switch moving part 122′ may rotate the switches 121, and the switch 121 may close the opening portion OP. A surface of each of the two switches 121 may contact the stage 11. Corners of the two switches 121 may contact each other. Accordingly, the switches 121 may close (e.g., completely close) the opening portion OP. In the second state, surfaces of the switches 121 and the seating portion ARE of the stage 11 may be coplanar with each other. Accordingly, in case that the target T (e.g., refer to FIG. 1) is seated on the seating portion ARE of the stage 11, the switches 121 may contact the target T.

According to embodiments, in an aging process of a display apparatus, burning of the display apparatus occurring in an opening portion of a seating portion may be reduced, and damage to the display apparatus occurring in a process of separating the display apparatus may be reduced.

The above description is an example of technical features of the disclosure, and those skilled in the art to which the disclosure pertains will be able to make various modifications and variations. Thus, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. An inspection device for a display apparatus, comprising:
a stage comprising:
a seating portion on which a target is seated; and
an opening portion located in the seating portion;
an opening/closing module that opens or closes the opening portion; and
an inspection module that inspects electrical characteristics of the target.

2. The inspection device of claim 1, wherein the opening/closing module comprises:
a switch contacting the target, on which the opening portion is closed; and
a switch moving part that moves the switch.

3. The inspection device of claim 2, wherein the switch moving part comprises a first moving part that moves the switch in a first direction so that the switch overlaps the opening portion in a plan view.

4. The inspection device of claim 3, wherein the switch moving part further comprises a second moving part that moves the switch in a second direction intersecting the first direction so that at least part of the switch is located in the opening portion.

5. The inspection device of claim 2, wherein the switch moving part comprises a hinge that rotates the switch about a rotational axis so that a surface of the switch is coplanar with the seating portion of the stage.

6. The inspection device of claim 2, wherein each of the seating portion of the stage and the switch comprises a metal material.

7. The inspection device of claim 1, wherein the opening portion comprises a first opening portion comprising a first portion extending in a direction parallel to a seating direction in which the target is seated.

8. The inspection device of claim 7, wherein the first opening portion further comprises a second portion extending from an end of the first portion in a direction intersecting the seating direction.

9. The inspection device of claim 7, wherein
the opening portion further comprises a second opening portion extending in a direction parallel to the seating direction, and
the second opening portion comprises:
a 2-1^{th} opening portion; and
a 2-2^{th} opening portion substantially symmetric to the 2-1^{th} opening portion with the first portion disposed between the 2-2^{th} opening portion and the 2-1^{th} opening portion.

10. The inspection device of claim 1, wherein the inspection module further comprises:
an inspector comprising a probe that applies a voltage to the target and detects an electrical signal generated by the target; and
an inspector moving part that moves the inspector so that the probe contacts the target.

11. An inspection method for a display apparatus, comprising:
seating a target on a seating portion of a stage;
closing an opening portion located in the seating portion of the stage;
inspecting electrical characteristics of the target; and
opening the closed opening portion.

12. The inspection method of claim 11, wherein the closing of the opening portion comprises moving a switch so that the switch contacts the target.

13. The inspection method of claim 12, wherein the moving of the switch comprises moving the switch in a first direction so that the switch overlaps the opening portion in a plan view.

14. The inspection method of claim 13, wherein the moving of the switch comprises moving the switch in a second direction intersecting the first direction so that at least part of the switch is located in the opening portion.

15. The inspection method of claim 12, wherein the closing of the opening portion comprises rotating the switch about a rotational axis so that a surface of the switch is coplanar with the seating portion of the stage.

16. The inspection method of claim 11, wherein the inspecting of the electrical characteristics of the target comprises:
moving a probe to contact the target; and
applying a voltage to the target by the probe to detect an electrical signal generated by the target.

17. The inspection method of claim 12, wherein each of the seating portion of the stage and the switch comprises a metal material.

18. The inspection method of claim 11, wherein the opening portion comprises a first opening portion comprising a first portion extending in a direction parallel to a seating direction in which the target is seated.

19. The inspection method of claim 18, wherein the first opening portion further comprises a second portion extending from an end of the first portion in a direction intersecting the seating direction.

20. The inspection method of claim 18, wherein
the opening portion further comprises a second opening portion extending in a direction parallel to the seating direction, and
the second opening portion comprises:
a 2-1^{th} opening portion; and
a 2-2th opening portion substantially symmetric to the 2-1^{th} opening portion with the first portion disposed between the 2-2^{th} opening portion and the 2-1^{th} opening portion.
